(19) United States
(12) Patent Application Publication
(10) Pub. No.: US 2012/0267674 A1
(43) Pub. Date: Oct. 25, 2012

(54) MOUNTING SUBSTRATE, LIGHT EMITTING BODY, AND METHOD FOR MANUFACTURING MOUNTING SUBSTRATE

(75) Inventors: Junichi Watari, Higashioumi-shi (JP); Yoshihiro Okawa, Higashiomi-shi (JP)

(73) Assignee: KYOCERA CORPORATION, Kyoto (JP)

(21) Appl. No.: 13/497,479

(22) PCT Filed: Sep. 24, 2010
(86) PCT No.: PCT/JP2010/066551

§ 371 Date: Mar. 21, 2012

(30) Foreign Application Priority Data
Sep. 24, 2009 (JP) 2009-219477
Apr. 27, 2010 (JP) 2010-101715

(51) Int. Cl. H05K 1/11; C04B 35/64; H05K 1/03; H01L 33/62; H05K 1/00

(52) U.S. Cl. 257/99; 174/250; 174/266; 174/255; 264/614; 257/E33.055

(57) ABSTRACT

A mounting substrate configured to mount a functional element thereon is provided. The mounting substrate includes an insulating base having a flat surface portion and a bank portion protruding from the flat surface portion and dividing the flat surface portion into a plurality of regions; and a conductor layer configured to electrically connect the functional element thereto. The conductor layer is adhered from the flat surface portion to a side surface of the bank portion on the base, and the regions divided by the bank portion are filled with the conductor layer.

### TECHNICAL FIELD

The present invention relates to a mounting substrate, a light emitting body, and a method for manufacturing the mounting substrate.

### BACKGROUND ART

For example, a functional element, such as a light emitting diode (LED), is configured to be mounted on a mounting substrate provided with an electrode (conductor layer) for supplying electric power to the functional element. Japanese Unexamined Patent Publication No. 2005-277380 describes an example of the mounting substrates configured to mount the light emitting element thereon.

FIG. 9 is a schematic perspective view of the light emitting body 100 described in Japanese Unexamined Patent Publication No. 2005-277380. In the light emitting body 100 of FIG. 9, the light emitting element 104 is mounted on the mounting substrate 102. The mounting substrate 102 is configured to mount the electrode 108 on a surface of a base 106 made of ceramics material.

The base 106 includes a slanting surface portion 112 disposed to surround a flat surface portion 110 having the light emitting element 104 mounted thereon, and has on the surface thereof the electrode 108 extending from the flat surface portion 110 to the slanting surface portion 112. The slanting surface portion 112 efficiently reflects the light emitted from the light emitting element 104 toward a direction perpendicular to the flat surface portion 110. The electrode 108 is formed by a so-called printed wiring technique, with which a metalized layer is formed by applying and firing an electrode paste in a predetermined pattern.

Meanwhile, the light emitting element 104, such as the LED, generates relatively large heat during the light emission therefrom. For example, the electrode 108 made of a metallic material has a higher coefficient of thermal expansion than the insulating base 106 made of a ceramics material. Therefore, thermal stress due to the heat generation of the light emitting element 104 occurs in the junction interface between the base 106 and the electrode 108. The conventional mounting substrate has suffered from the problem that the electrode 108 is apt to easily separate from the base 106 due to the thermal stress occurred in the junction interface.

### SUMMARY OF THE INVENTION

A mounting substrate according to an embodiment of the present invention includes an insulating base which has a flat surface portion and a bank portion protruding from the flat surface portion and dividing the flat surface portion into a plurality of regions; and a conductor layer configured to electrically connect a functional element thereto. The conductor layer is adhered from the flat surface portion to a side surface of the bank portion on the base. The regions divided by the bank portion are filled with the conductor layer.

A light emitting body according to an embodiment of the present invention includes the mounting substrate, and a functional element disposed on the mounting substrate. The functional element is a light emitting element.

A method for manufacturing a mounting substrate according to an embodiment of the present invention includes: obtaining a green compact comprising a flat surface portion and a bank portion protruding from the flat surface portion by press molding a mixture of ceramics material powder; and obtaining a sintered body by firing the green compact. The method further includes filling regions of the flat surface portion divided by the bank portion on the sintered body, with paste composed mainly of a conductor material; and forming a conductor layer so as to fill the regions divided by the bank portion by heating the paste in a state in which the regions are filled with the paste.

The mounting substrate and the light emitting body are capable of suppressing the electrode separation caused by temperature variations. The manufacturing method permits high-precision control of the electrode shape.

### BRIEF DESCRIPTION OF THE DRAWINGS

FIG. 1(a) is a schematic perspective view for explaining one embodiment of the mounting substrate of the present invention, in which a conductor layer 8 and an electrode body 9 described later are indicated by applying color thereto; FIG. 1(b) is a schematic perspective view of a base constituting the mounting substrate as shown in FIG. 1(a);

FIG. 2(a) is a top view of the mounting substrate shown in FIG. 1, in which the conductor layer 8 and the electrode body 9 described later are indicated by applying color thereto; FIG. 2(b) is a schematic diagram of a cross section taken along the line B-B in FIG. 2(a); FIG. 2(c) is a schematic diagram of a cross section taken along the line C-C in FIG. 2(a); FIG. 2(d) is an enlarged view of a part indicated by broken lines in FIG. 2(b);

FIGS. 3(a) and 3(b) are diagrams showing other embodiments of bank portions provided on the base, namely, enlarged views of the vicinity of the bank portions on the base;

FIG. 4(a) is a schematic top view for explaining an embodiment of the light emitting body of the present invention constructed from the mounting substrate as shown in FIGS. 1 and 2; FIG. 4(b) is a schematic diagram of a cross section taken along the line B-B in FIG. 4(a); FIG. 4(c) is a schematic diagram of a cross section taken along the line C-C in FIG. 4(a);

FIG. 5(a) is a schematic perspective view for explaining an example of a light emitting device constructed from the light emitting body shown in FIG. 4; FIG. 5(b) is a schematic sectional view thereof;

FIG. 6(a) is a schematic perspective view for explaining another embodiment of the mounting substrate of the present invention; FIG. 6(b) is a schematic perspective view of the base constituting the mounting substrate;

FIG. 7(a) is a schematic top view for explaining another embodiment of the light emitting body of the present invention constructed from the mounting substrate as shown in FIG. 6; FIG. 7(b) is a schematic diagram of a cross section taken along the line B-B in FIG. 7(a); FIG. 7(c) is a schematic diagram of a cross section taken along the line C-C in FIG. 7(a);

FIG. 8(a) is a schematic perspective view for explaining a light emitting device constructed from the light emitting body shown in FIG. 7; FIG. 8(b) is a schematic sectional view thereof; and

FIG. 9 is a schematic perspective view of an example of conventional mounting substrates.

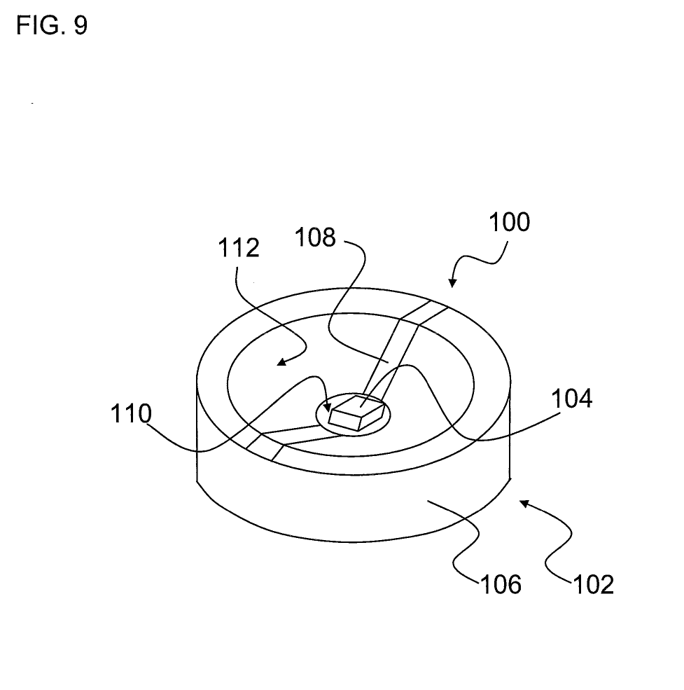

### PREFERRED EMBODIMENTS FOR CARRYING OUT THE INVENTION

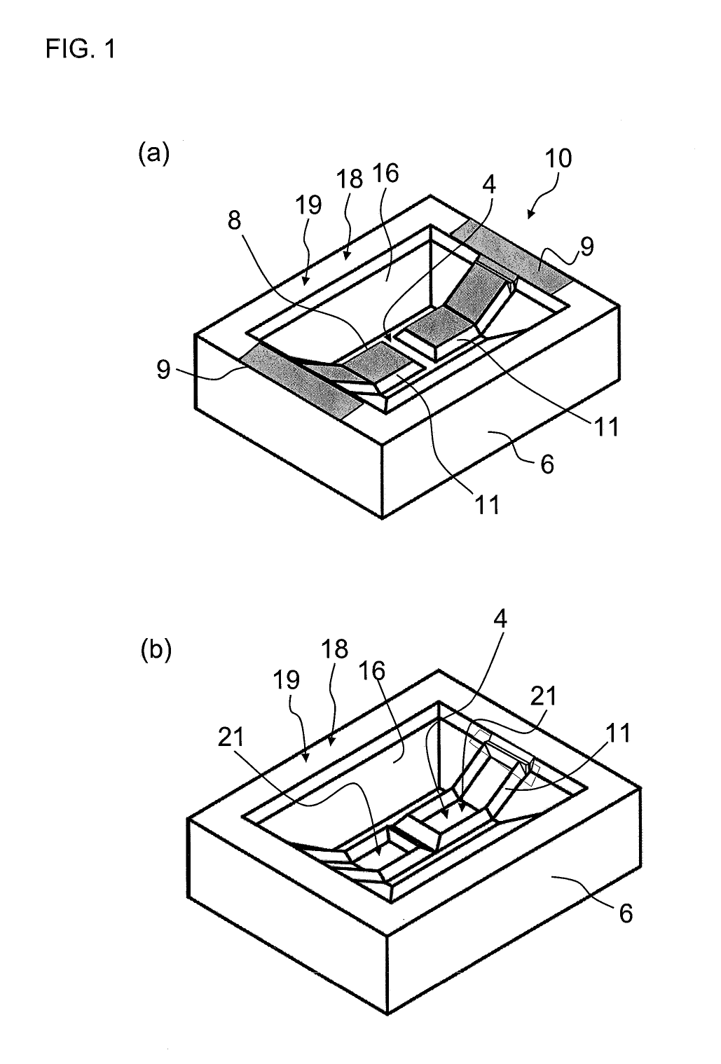

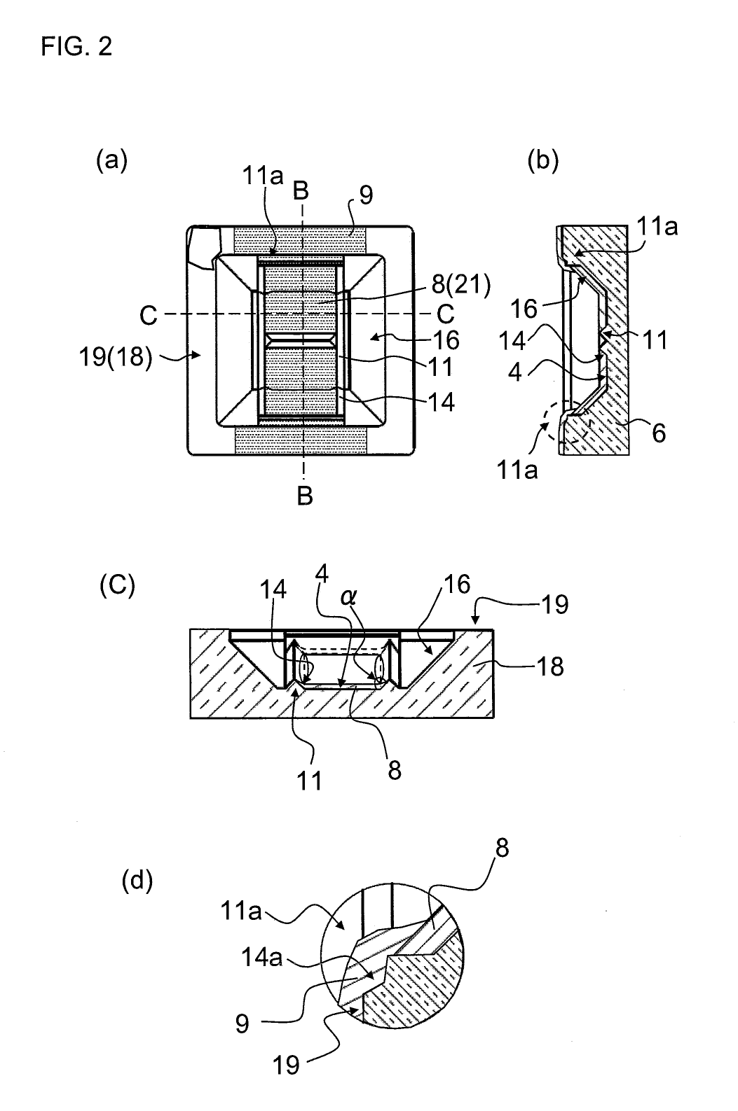

A first embodiment of the mounting substrate of the present invention is described with reference to the accompanying drawings. FIGS. 1 and 2 are the schematic explanatory drawings for explaining the mounting substrate 10 that is the first embodiment of the mounting substrate of the present invention.

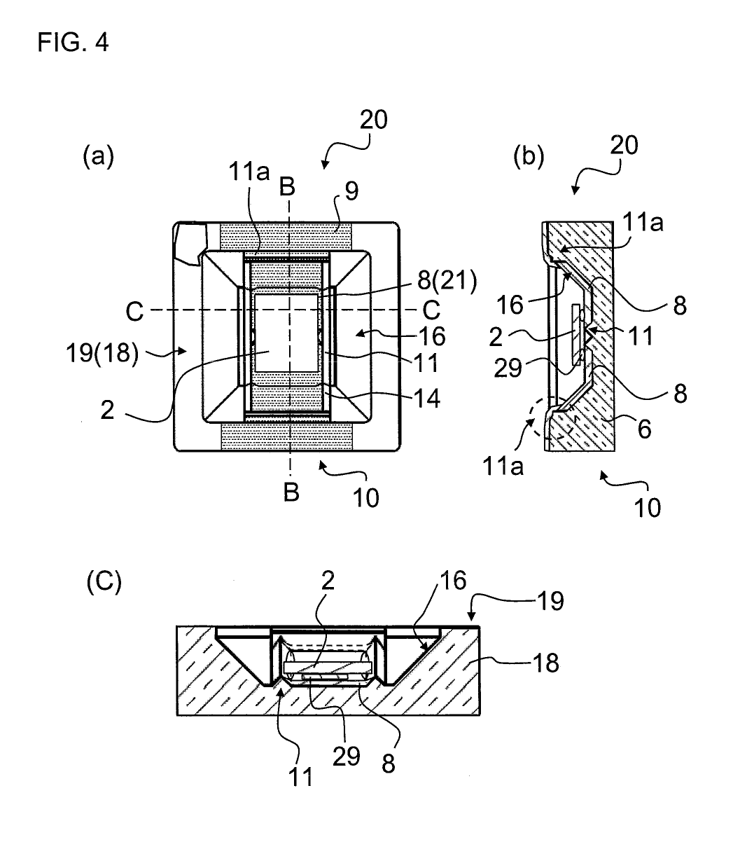

The mounting substrate 10 is used for mounting thereon a later-described LED element 2 that is the light emitting element, and the light emitting body 20 is constructed from the LED element 2 and the mounting substrate 10, as shown in FIGS. 4(a) to 4(c).

The mounting substrate 10 includes a base 6, a conductor layer 8 disposed on a surface of the base 6, and an electrode body 9.

The base 6 includes a flat surface portion 4 and a frame body 18 including a slant surface 16 disposed to surround the circumference of the flat surface portion 4. A top surface 19 of the frame body 18 is substantially parallel to the flat surface portion 4.

The base 6 also includes bank portions 11 protruding from the flat surface portion 4 and the slant surface 16, respectively. These bank portions 11 divide the flat surface portion 4 into a plurality of regions. In the present embodiment, these bank portions 11 are disposed continuously from the flat surface portion 4 to the slant surface 16, and are annually continuous with each other in a top view perpendicular to the flat surface portion 4, as shown in FIG. 1(b). These bank portions 11 have a substantially triangular cross-sectional shape whose cross-sectional area decreases toward a top thereof. An angle α formed by a side surface 14 of the bank portion 11 and the flat surface portion 4 of the base 6 is an obtuse angle, namely, 90°<α.

In the mounting substrate 10, two regions 21 surrounded by the continuous bank portions 11 are disposed adjacent to each other. The conductor layer 8 is disposed in each of these two regions 21. The conductor layers 8 in the adjacent regions 21 are separated from each other and are electrically independent from each other.

The base 6 is composed mainly of ceramics, for example. In the mounting substrate 10 for mounting the LED element 2, the ceramics is preferably composed mainly of alumina, for example. The alumina reflects relatively satisfactorily the light emitted from a general LED element. Microstructures of several millimeters to 1 millimeters or less can be relatively easily formed with a die. The electrode can be formed on the surface relatively easily by using a metallization technique. From these viewpoints, the alumina is suitably used as a material constituting the base 6. Other ceramic materials and resin materials can also be used according to the application. That is, no special limitation is imposed on the material of the base 6.

The conductor layer 8 is disposed to fill the interior of the regions 21, and is adhered from the flat surface portion 4 to the side surface 14 of the bank portion 11 on the base 6, as shown in FIGS. 2(b) and 2(c). The conductor layer 8 is constructed from a well-known multi-layer metal film structure in which, for example, a plating layer is stacked on a metalized layer. The conductor layer 8 is constructed by stacking, for example, an Ni plating layer and an Au plating layer on an Mo—Mn metalized layer. In the present embodiment, the height of the conductor layer 8 is set lower than the height of the bank portions 11. The surface of the conductor layer 8 rises toward the bank portions 11. Alternatively, the conductor layer 8 may be higher than the height of the bank portions 11. For example, the conductor layer 8 may be formed into a shape that it upheaves from the bank portions 11 by surface tension. The conductor layer 8 is continuously disposed from the flat surface portion 4 to the slant surface 16.

For example, when heat is generated from the functional element, such as the LED element, mounted on the mounting substrate 10, the temperature of the mounting substrate 10 rises, and the conductor layer 8 and the base 6 are subject to thermal expansion in accordance with the heat generation. The base 6 composed mainly of ceramics, such as alumina, and the conductor layer 8 composed of the multilayer metal layer differ from each other in coefficient of thermal expansion, namely, the coefficient of thermal expansion in accordance with light emission. In the mounting substrate 10, the conductor layer 8 is adhered not only over the flat surface portion 4, but also over the side surface 14 of the bank portions 11 on the base 6, thus producing strong adhesion strength between the base 6 and the conductor layer 8. Further in the present embodiment, the surface of the conductor layer 8 rises toward the bank portions 11. Accordingly, the adhesive area between the base 6 and the conductor layer 8 is larger than the case where the conductor layer 8 has a constant height. Therefore, the junction strength between the conductor layer 8 and the bank portions 11 is higher than that in the case where the conductor layer 8 has the constant height.

Even when the conductor layer 8 undergoes a larger expansion than the base 6, the expansion along a direction parallel to the flat surface portion 4 of the conductor layer 8 is suppressed by the bank portions 11. Therefore, thermal stress along the direction parallel to the flat surface portion 4, which occurs at the junction interface between the flat surface portion 4 and the conductor layer 8, can be suppressed in the mounting substrate 10, thereby reducing the occurrence of separation of the conductor layer 8 due to the thermal stress.

The bank portions 11 have the substantially triangular cross section and relatively high mechanical strength. Therefore, even when thermal stress occurs in accordance with the heat generation of the mounted functional element, the bank portions 11 are relatively less susceptible to cracking and fracture.

In the present embodiment, the angle α formed by the flat surface portion 4 and the side surface 14 is 90°<α. As compared to a case where the angle α is 90°≦α, the conductor layer 8 is susceptible to expansion in a direction perpendicular to the flat surface portion 4 in the present embodiment. Hence, when the conductor layer 8 expands, the thermal stress in the direction perpendicular to the flat surface portion 4 is prone to dispersion in the direction perpendicular to the flat surface portion 4 than the case where the angle α is 90°≦α. This suppresses the thermal stress along the direction parallel to the flat surface portion 4 which occurs at the junction interface between the base 6 and the conductor layer 8.

Further in the mounting substrate 10, the position and shape of the conductor layer 8 are defined by the side surfaces 14 of the bank portions 11. This allows the mounting substrate 10 to have relatively high shape and position accuracies of the conductor layer 8. For example, even for a microelectrode having an electrode width of 1 mm or less, the position and shape thereof are defined with high accuracy. Methods of manufacturing the base 6 and the conductor layer 8 are described later in details.

The electrode body 9 is disposed on the top surface 19 of the frame body 18, and is connected to the conductor layer 8 disposed on the slant surface 16 in such a manner that a part of the electrode body 9 rides over the bank portions 11. As shown in FIG. 2(d), in bank portion parts 11a located in the vicinity of the top surfaces 19 of the annularly connected bank portions 11, each side surface 14a close to the top surface 19 is indented in the shape of a groove. The electrode body 9 is connected to the conductor layer 8 in such a manner that it rides over the bank portion parts 11a along the side surface 14a.

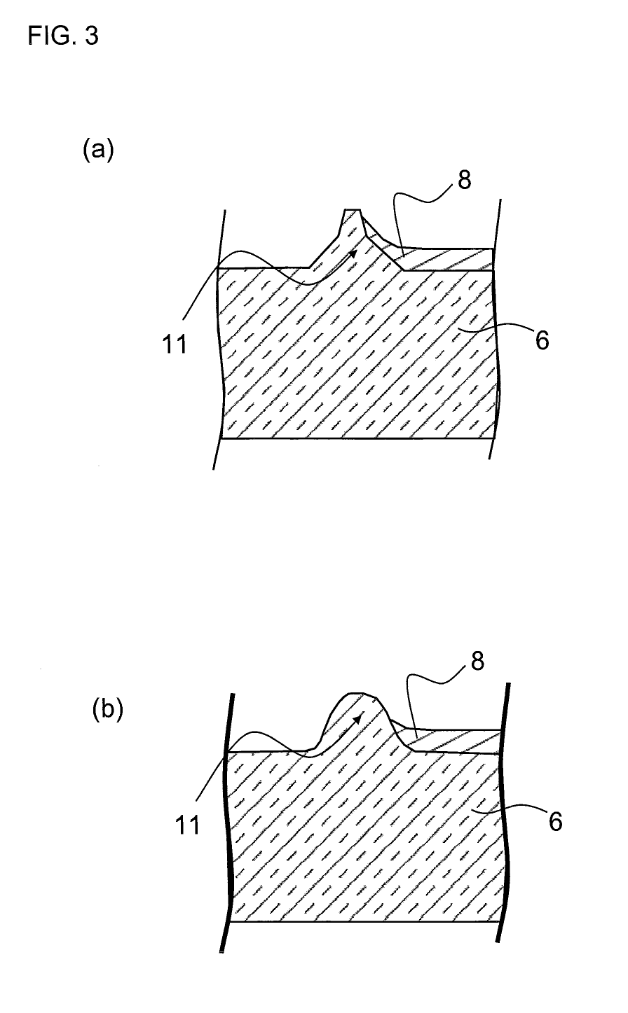

No special limitation is imposed on the cross-sectional shape of the bank portions 11. As shown in FIG. 3(a), peripheral edge lines of the bank portions 11 may be in a multistage shape having a plurality of bent portions. As shown in FIG. 3(b), the peripheral edge lines of the bank portions 11 may be in such a shape that a plurality of curves having different curvatures are connected to each other. The shape of the bank portions 11 can be changed variously according to the necessary characteristics.

The light emitting body 20 as shown in FIGS. 4(a) to 4(c) includes the mounting substrate 10 and the LED element disposed on the mounting substrate 10 as described above. The LED element 2 is a well-known light emitting diode element, and is connected to the conductor layer 8 of the mounting substrate 10 through a flip-chip junction layer 29, such as solder. In the light emitting body 2, the LED element 2 includes unshown two electrodes (a positive electrode and a negative electrode), and the individual electrodes are respectively connected to one of two electrically independent conductor layers 8 by a flip-chip-bonding. In the light emitting body 20, current is supplied through the conductor layer 8 to the LED element 2, and the LED element 2 emits light according to the supplied current.

As described above, the conductor layer 8 of the mounting substrate 10 is disposed continuously from the flat surface portion 4 to the slant surface 16. The conductor layer 8 is also connected to the electrode body 9 formed so that it rides over the bank portions 11a. The electrode body 9 of the light emitting body 20 is connected to an external power supply through, for example, a bonding wire or the like, and the LED element 2 emits light by the electric power supplied through the external power supply. In the light emitting body 20, the bonding wire and the LED element 2 can be separated from each other, thereby suppressing damage or the like to the LED element 2 in the wiring process, such as bonding processing.

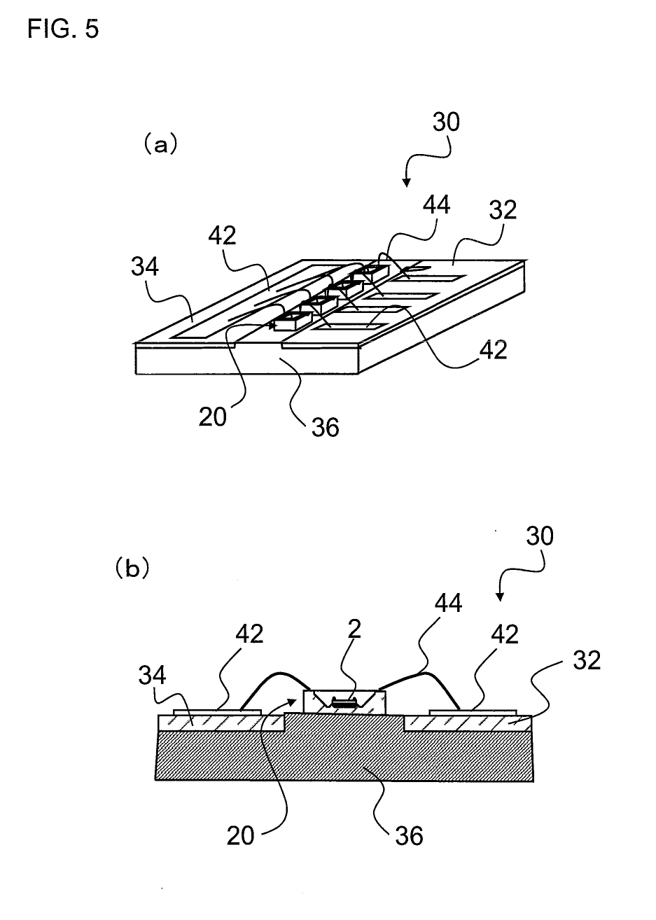

Next, an embodiment of the light emitting device including the foregoing light emitting body 20 is described with reference to FIGS. 5(a) to 5(c). The light emitting device 30 includes the light emitting body 20, a heat sink 36, a pair of printed circuit boards 32 and 34, and a wire 44.

The heat sink 36 is composed mainly of metal and alloy having excellent heat conduction properties, such as copper (Cu). The light emitting body 20 is mounted on the surface of the heat sink 36 through adhesive or the like. These printed circuit boards 32 and 34 are made of an insulating material, such as resin, and have conductive wiring patterns 42 formed on their respective surfaces. The wiring patterns 42 are connected to the electrode body 9 of the light emitting body 20 by the wire 44 that is a well-known bonding wire. In the light emitting device 30, the wiring patterns 42 are thus electrically connected to the conductor layer 8 through the wire 44 and the electrode body 9. In the light emitting device 30, the wiring patterns 42 are connected to unshown external power supplies, and the plurality of wiring patterns 42 are respectively connected to the power supplies each having a predetermined potential. Thereby, the conductor layer 8 of the mounting substrate 10 of the light emitting body 20 is held at a predetermined potential, so that electrical current passes through the LED element 2 and the LED element 2 emits light.

The LED element 2 generates heat along with light emission. Therefore, in the vicinity of a region for positioning the LED element 2, the conductor layer 8 and the base 6 are subject to thermal expansion in accordance with the heat generation. In the light emitting body 20, as described above, the conductor layer 8 is deposited not only over the flat surface portion 4 of the mounting substrate, but also over the slant surface 16 of the bank portions 11 of the base 6, thus achieving high adhesion strength between the base 6 and the conductor layer 8. Further, the expansion in the width direction of the conductor layer 8 is suppressed by the bank portions 11, thus suppressing the electrode separation due to the thermal stress. Even when the thermal stress caused by the heat generation of the LED element 2 is applied to the base 6, the bank portions 11 are relatively less susceptible to cracking, breakage, or the like, and the light emitting device 30 has relatively high operational reliability.

For example, the light emitting body 20 can be manufactured in the following manner.

Firstly, the base 6 is manufactured. That is, alumina powder and sintering additives powder are mixed together, and water is added thereto, followed by wet grinding. Thereafter, slurry is manufactured by adding and mixing polyvinyl alcohol or the like as organic binder. The slurry is formed into granules by spray drying. The granules are formed into a green compact by press molding using a die. The shape of the die is so designed that the substrate shape can be obtained after firing. For example, the die includes indents so that the bank portions can be formed after sintering. The base 6 composed mainly of alumina is manufactured by firing the green compact at 1500-1700° C. Thereafter, as required, in order to remove burr, the base surface may be subjected to barrel polishing, and then washing and drying. The height of the bank portions is, for example, 0.02-0.4 mm, preferably 0.05-0.2 mm. The width of the bank portions is, for example, 0.05-0.6 mm, preferably 0.1-0.4 mm.

Subsequently, the conductor layer 8 is formed on the base 6. In the formation of the conductor layer 8, firstly, paste containing Mo powder and Mn powder is applied to the regions 21 surrounded by the bank portions 11 on the manufactured base 6. In the paste application, a predetermined amount of the paste droplets is dropped into the regions 21 by using a well-known potting device. The paste is wet spread over the surface of the base 6 composed mainly of the ceramics, but the wet spread is kept back by the bank portions 11. Owing to the bank portions 11 provided on the base 6, the paste can be defined and positioned with high precision in the range of the regions surrounded by the bank portions 11. Thereafter, with the paste positioned so, the entirety is heat treated in a reducing atmosphere. A deposited first metal layer is formed on the base 6 by the heat treatment. Subsequently, a plating layer as a second metal layer is formed on the first metal layer. Plating, specifically Ni plating and Au plating are carried out in the order listed. The Ni plating thickness is, for example, 1-10 μm, and the Au plating thickness is, for example, 0.1-3 μm. The mounting substrate 10 can be manufactured, for example, in the foregoing manner.

Thereafter, the electrode body 9 is formed. The electrode body 9 disposed on the flat top surface 19 may be manufactured by using a well-known printed wiring technique, such as screen printing method. The side surface 14a of the bank portion 11a is inclined toward a vertical lower side as it approaches the center of the flat surface portion 4 from the top surface 19. Even when the electrode paste is applied by screen printing or the like, the electrode paste rides over the bank portion 11a along the side surface 14a, thus being connected to the conductor layer 8. For example, the metalized layer having a predetermined shape is formed by applying the paste containing Mo powder and the Mn powder in a predetermined shape with the screen printing method, followed by heat treatment in a reducing atmosphere. In this case, the paste rides over the bank portion 11a and is connected to the conductor layer 8. Subsequently, the electrode body 9 is obtained by sequentially stacking Ni plating and Au plating on the surface of the metalized layer.

Then, the LED element 2 is mounted on the manufactured mounting substrate 10. An unshown electrode of the LED element 2 is mounted oppositely to the conductor layer 8, and the electrode of the LED element 2 and the conductor layer 8 are connected to each other by flip-chip junction. As a method of mounting the LED element 2, soldering method, wire bonding for making-bonding through a metal wire, or the like, may be employed.

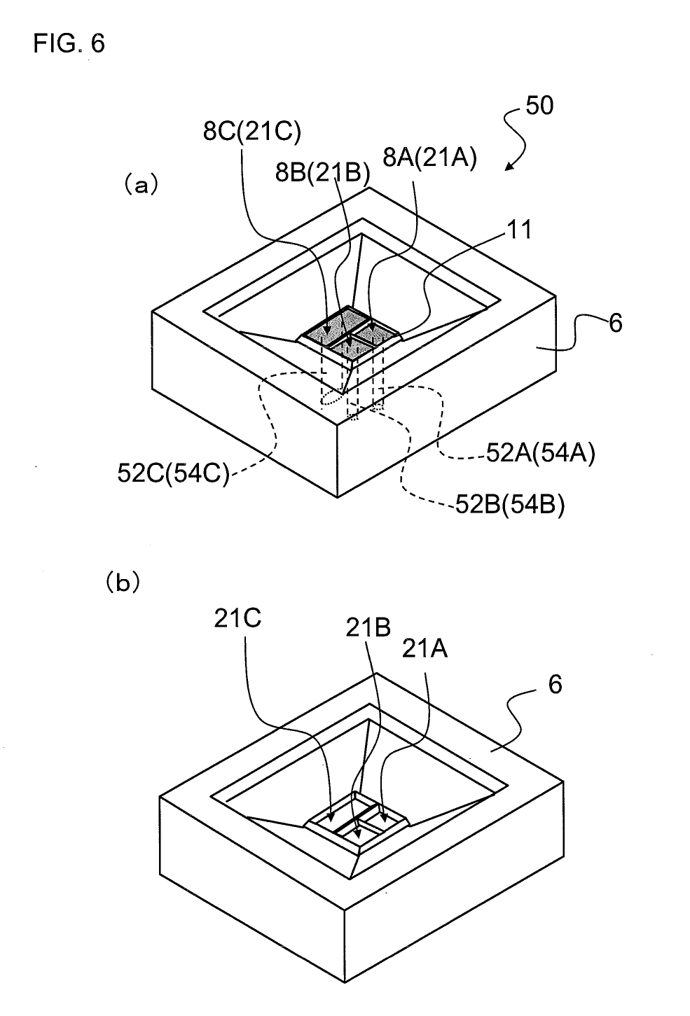

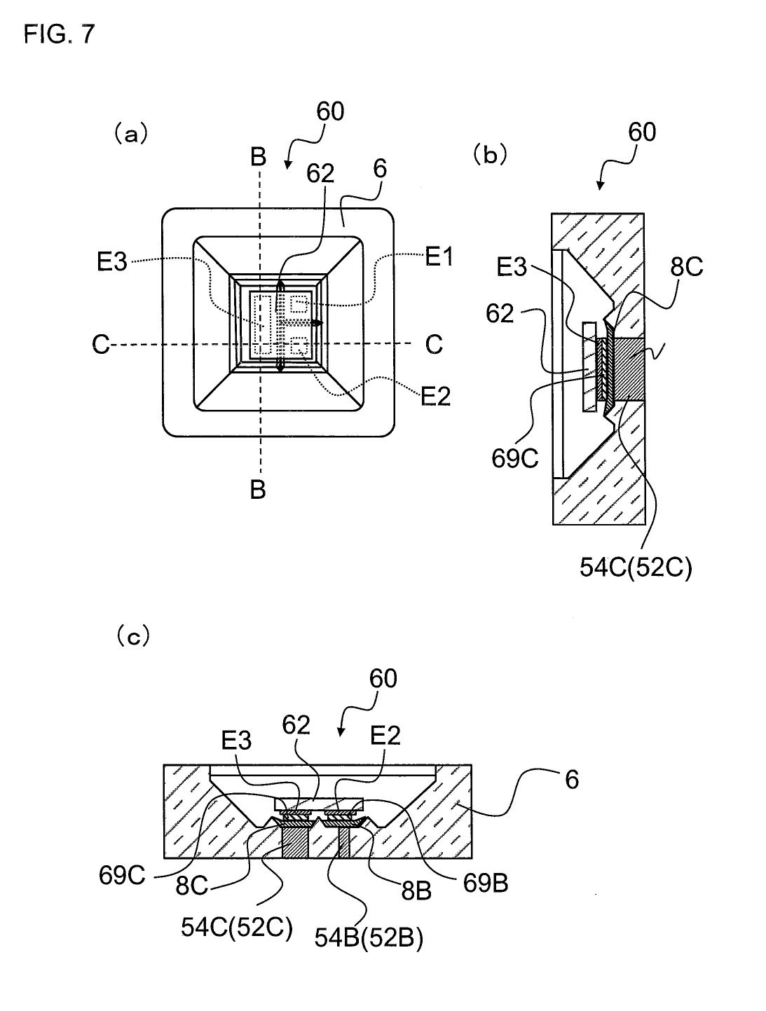

Next, a light emitting body 60 of a second embodiment of the present invention is described with reference to FIGS. 6(a) to 6(c) and FIGS. 7(a) to 7(c). Components similar to those in the first embodiment are identified by the same reference numerals as the first embodiment. Descriptions of configurations similar to those in the first embodiment are omitted in some cases.

The mounting substrate 50 of the second embodiment is similar to the first embodiment in the points that it includes the insulating base 6 and the conductor layer 8 disposed on the surface of the base 6, and that the bank portions 11 protruding from the flat surface portion 4 are disposed on the flat surface portion 4. The second embodiment differs from the first embodiment in the manner of dividing the flat surface portion 4 by the bank portions 11. In the second embodiment, the flat surface portion 4 is divided by the bank portions 11 into three regions (region 21A, region 21B, and region 21C), and conductor layers 8A to 8C are respectively disposed in these regions similarly to the first embodiment.

Unlike the first embodiment, a plurality of through holes 52A to 52C are in the base 6 in the mounting substrate 50 of the second embodiment. In the second embodiment, conductor members (via conductors) 54A to 54C connected to the conductor layers 8A to 8C, respectively, are disposed in these through holes 52A to 52C. These conductor members 54A to 54C are made of a metallic material composed mainly of, for example, Cu—W alloy, and have higher thermal conductivity than the base 6. Among these conductor members 54A to 54C, the conductor member 54C has the largest diameter and has the highest heat conduction efficiency.

Also in the light emitting body 60 of the second embodiment, an LED element 62 is connected to the mounting substrate 50 through a flip-chip junction layer 69, such as solder, as shown in FIG. 7. The LED 62 has, on one major surface thereof, two electrodes of a positive electrode E1 and a negative electrode E2. The positive electrode E1 is connected to the conductor layer 8A through a junction layer 69A, and the negative electrode E2 is joined to the conductor layer 8B through a junction layer 69B. In the second embodiment, the LED element 62 further has a metal layer E3 on the major surface, and the metal layer E3 is connected to the conductor layer 8C through a junction layer 69C.

The mounting substrate 50 includes the conductor members 54A to 54C having higher thermal conductivity than the base 6, and heat is released from these conductor member 54A to 54C at high efficiency. Therefore, thermal stress at the interface between the base 6 and each of the conductor layers is relatively reduced. Further, electric power is supplied to the LED element 62 through the conductor members 54A and 54B. This eliminates the need to form a conductor pattern on the slant surface 16 of the base 6, thereby somewhat mitigating spatial variations in the intensity of light reflected from the slant surface 16. Furthermore, in the mounting substrate 50, the LED element 62 includes not only the positive electrode E1 and the negative electrode E2, but also the electrode E3 having a relatively large area. The electrode E3 is connected to the conductor member 54C having high conduction efficiency. This makes it easier for the heat generated in the LED element 62 to be released into the outside through the electrode E3 and the conductor member 54C.

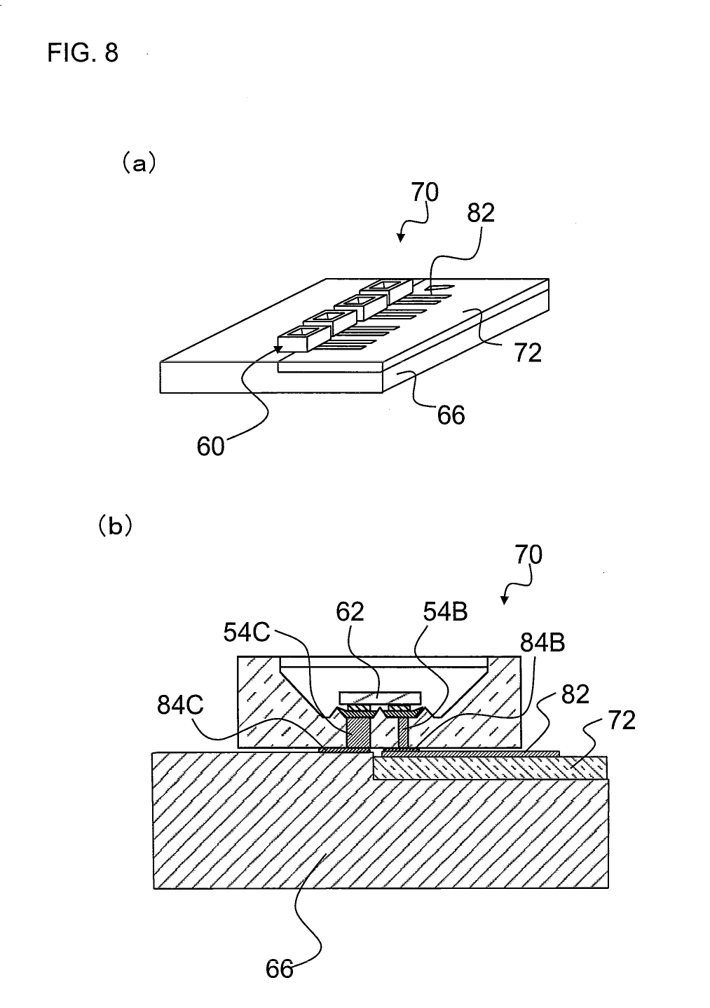

Next, a light emitting device 70 constructed from a plurality of the light emitting bodies 60 is described with reference to FIGS. 8(a) and 8(b). The light emitting device 70 includes a heat sink 66 and a printed circuit board 72. The second embodiment employs the single printed circuit board 72. The printed circuit board 72 is made of an insulating material, such as resin and ceramics, and has conductive wiring patterns 82 formed on a surface thereof. These wiring pattern 82 are connected to the conductor members 54A and 54B of each of the light emitting bodies 60 through junction layers 84B and 84C composed of solder or the like, respectively. These wiring patterns 82 are respectively connected to unshown external power supplies, and the plurality of wiring patterns 82 are respectively connected to the power supplies each having a predetermined potential. Thereby, the conductor layer 8A and the conductor layer 8B of the mounting substrate 50 of each of the light emitting bodies 60 are held at a predetermined potential, and electrical current passes through the LED element 62, and the LED element 62 emits light.

The heat sink 66 is composed mainly of metal and alloy having excellent heat conduction properties, such as copper (Cu). In the second embodiment, the heat sink 66 is connected through the junction layer 84C, such as solder, to the conductor member 54C joined with the LED element 62.

The LED element 62 generates relatively large heat along with light emission. In the light emitting device 70, heat is released with high efficiency from the conductor members 54A to 54C of the light emitting body 60, and hence the heat stress at the interface between the base 6 and each of the conductor layers is relatively reduced. Especially, the conductor member 54C having the largest diameter among the conductor members 54A to 54C is joined to the heat sink 66 having high thermal conductivity. Thus, the heat generated along with the light emission of the LED element 62 can be released through the conductor member 54C with high efficiency.

In the mounting substrate 50, the electric power is supplied from the conductor members 54B and 54C disposed in the base 6. Unlike the first embodiment, it is unnecessary to dispose electrodes and the like on the top surface 19 of the base 6, and then perform wire bonding. In the second embodiment, even when the plurality of mounting substrates 50 are disposed close to each other as shown in FIG. 8, the conductor layers 8A to 8C between the mounting substrates 50 are less likely to come into electrical contact with each other, thereby allowing the plurality of mounting substrates 50 to be positioned in high density. Additionally, even when the mounting substrates 50 are positioned in the high density, the heat can be released from the conductor members 54A to 54C with high efficiency.

The light emitting bodies 60 according to the second embodiment are also unsusceptible to failure caused by the light emission of the LED element 62, such as separation of the conductor layer 8. The light emitting bodies 60 have relatively high electrical performance and luminous efficiency, and also have relatively high operational reliability.

The light emitting bodies 60 of the second embodiment can be manufactured in the steps basically similar to those in the light emitting body 20 of the first embodiment. The through hole 52 of the base 6 may be formed when the base 6 is molded using a die that has a protruded portion corresponding to the through hole 52. Alternatively, after manufacturing a green compact without a through hole, the through hole 52 may be formed by laser processing or the like. The conductor members 54A to 54C may be formed inside the through holes 52A to 52C by a well-known plating process. Alternatively, the conductor members 54A to 54C may be formed by burying paste, which is prepared by mixing together, for example, copper (Cu) powder and tungsten (W) powder, in the through holes 52A to 52C by press printing, followed by firing. No special limitation is imposed on the method for manufacturing the light emitting bodies 60, and the like.

The light emitting bodies of the present invention are suitably applicable to, for example, domestic lighting, industrial lighting, such as ultraviolet irradiation devices, and back lights of liquid crystal displays. Not only the light emitting elements such as LEDs, but also semiconductor elements and the like may be mounted on an mounting substrate.

While the first and second embodiments of the present invention have been described above, the present invention is not limited to the examples in the foregoing embodiments, and various changes or modifications may be made thereto without departing from the scope of the present invention.

### DESCRIPTION OF REFERENCE NUMERALS

2 LED element
6 base
8 conductor layer
9 electrode body
10, 50 mounting substrates
11, 11a bank portions
14 side surface of bank portion
16 slant surface of frame body
18 frame body
19 top surface of frame body
20 light emitting body
21 region
30, 70 light emitting devices
32, 34 printed circuit boards
36 heat sink
42 wiring pattern
44 wire
52A-52C through holes
54A-54C conductor members (via conductors)
69 flip-chip junction layer

1. A mounting substrate configured to mount a functional element thereon, comprising:
an insulating base comprising
a flat surface portion and
a bank portion protruding from the flat surface portion and dividing the flat surface portion into a plurality of regions; and
a conductor layer configured to electrically connect the functional element thereto, wherein
the conductor layer is adhered from the flat surface portion to a side surface of the bank portion on the base, and the regions divided by the bank portion are filled with the conductor layer.

2. The mounting substrate according to claim 1, wherein
the base comprises a slant surface continuous with a peripheral edge of the flat surface portion, and
the bank portion and the conductor layer are continuously disposed from the flat surface portion to the slant surface.

3. The mounting substrate according to claim 1, wherein, in at least one of the regions divided by the bank portion, a height of the conductor layer filling the region is lower than a height of the bank portion.

4. The mounting substrate according to claim 1, wherein an angle formed by the side surface of the bank portion and the flat surface portion is an obtuse angle.

5. The mounting substrate according to claim 1, wherein the base is configured to dispose a through hole therein, and the through hole is located in the regions divided by the bank portion.

6. The mounting substrate according to claim 1, wherein a via conductor made of an identical material to the conductor layer is disposed in the through hole.

7. The mounting substrate according to claim 1, wherein the base is composed mainly of ceramics.

8. The mounting substrate according to claim 7, wherein the ceramics is alumina.

9. A light emitting body, comprising:
the mounting substrate according to claim 1; and
a functional element disposed on the mounting substrate, wherein
the functional element is a light emitting element.

10. The light emitting body according to claim 9, wherein the light emitting element is connected to the conductor layer by a flip-chip-bonding.

11. A method for manufacturing a mounting substrate, comprising:
obtaining a green compact comprising a flat surface portion and a bank portion protruding from the flat surface portion by press molding a mixture of ceramics material powder;
obtaining a sintered body by firing the green compact;
filling regions of the flat surface portion divided by the bank portion on the sintered body, with paste composed mainly of a conductor material; and
forming a conductor layer that fills the regions divided by the bank portion by heating the paste in a state in which the regions are filled with the paste.
